(19) United States
(12) Patent Application Publication
(10) Pub. No.: US 2014/0340850 A1
(43) Pub. Date: Nov. 20, 2014

(54) COOLING ASSEMBLY

(71) Applicant: HON HAI PRECISION INDUSTRY CO., LTD., New Taipei (TW)

(72) Inventor: CHEN-LU FAN, New Taipei (TW)

(73) Assignee: HON HAI PRECISION INDUSTRY CO., LTD., New Taipei (TW)

(21) Appl. No.: 14/137,265

(22) Filed: Dec. 20, 2013

(30) Foreign Application Priority Data
May 14, 2013 (TW) 102116970

(51) Int. Cl. H05K 7/20

(52) U.S. Cl. CPC H05K 7/20509
USPC 361/720

(57) ABSTRACT

A cooling assembly includes a chassis, a circuit board secured to the chassis, a cooling layer, a cooler secured to the circuit board, and a housing receiving the cooler and the circuit board and secured to the chassis. The housing includes a front plate. The cooling layer is located between the front plate and the cooler. A first surface of the cooling layer is secured to the cooler. A second surface of the cooling layer, opposite to the first surface, is secured to the front plate. The cooling layer transfers heat from the cooler to the housing to cool a heating element on the circuit board.

### BACKGROUND

1. Technical Field

The present disclosure relates to cooling systems, and particularly to a cooling assembly in an electronic device.

2. Description of Related Art

A cooling assembly, including a cooler and a fan, is generally used for cooling an electronic device. However, the fan is always excluded because of miniaturization of the electronic devices and the cooling of the device is poor, which may cause high temperatures of electronic components and as such damage the electronic components. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a cooling assembly.

FIG. 2 is an isometric view of a mounting member of the cooling assembly of FIG. 1.

FIG. 3 is an enlarged view of a circled portion III of the cooling assembly of FIG. 1.

FIG. 4 is an assembled, isometric view of the cooling assembly of FIG. 1.

FIG. 5 is a cross section view of the assembled cooling assembly of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

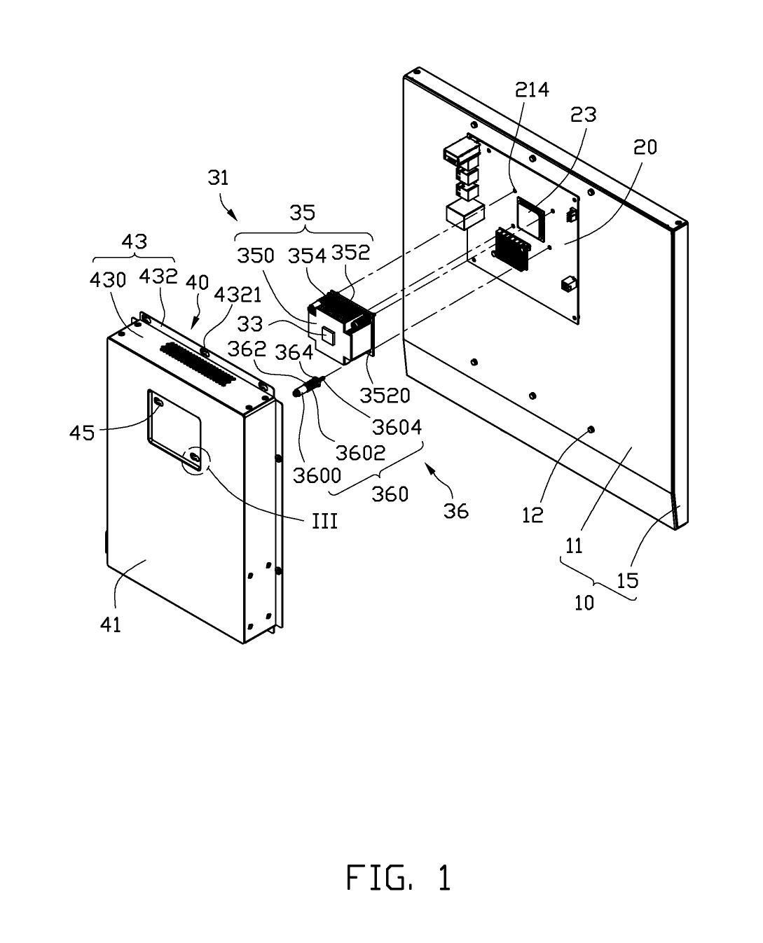

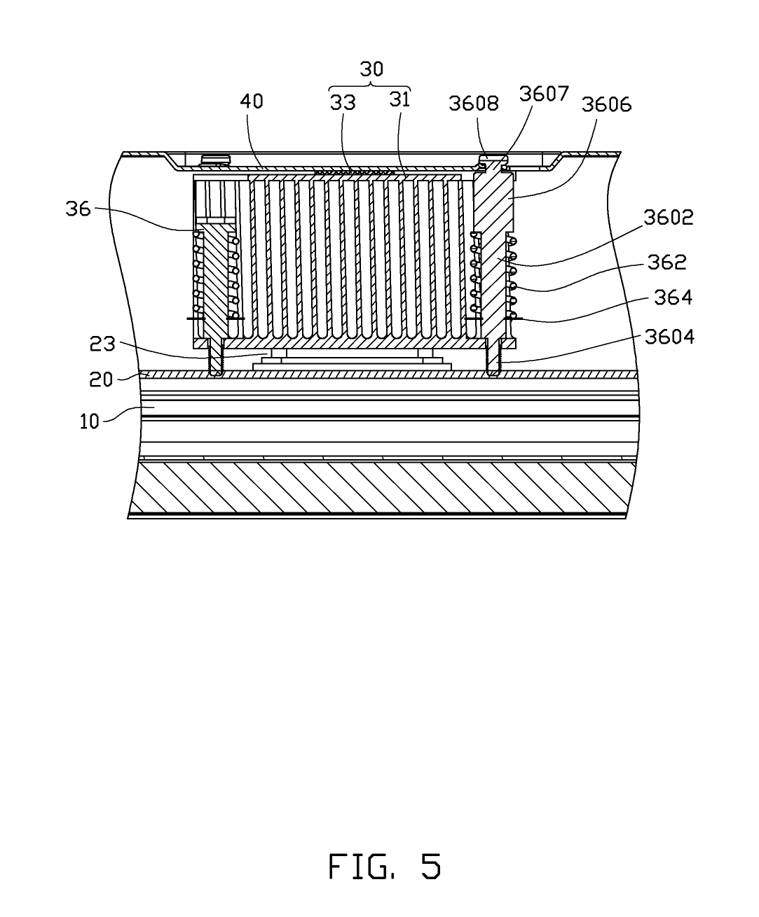

FIG. 1 and FIG. 5 show one embodiment of a cooling assembly. The cooling assembly comprises a chassis 10, a circuit board 20 secured to the chassis 10, a cooling module 30, and a housing 40.

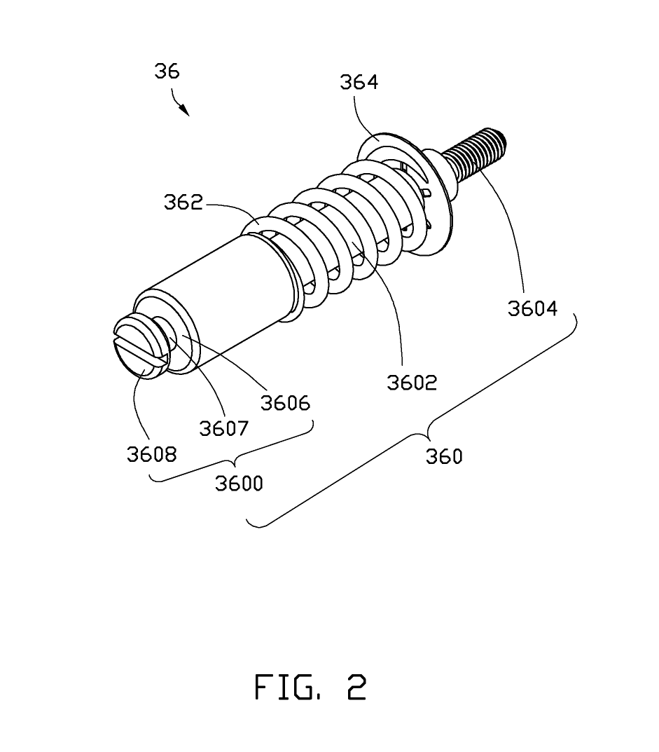

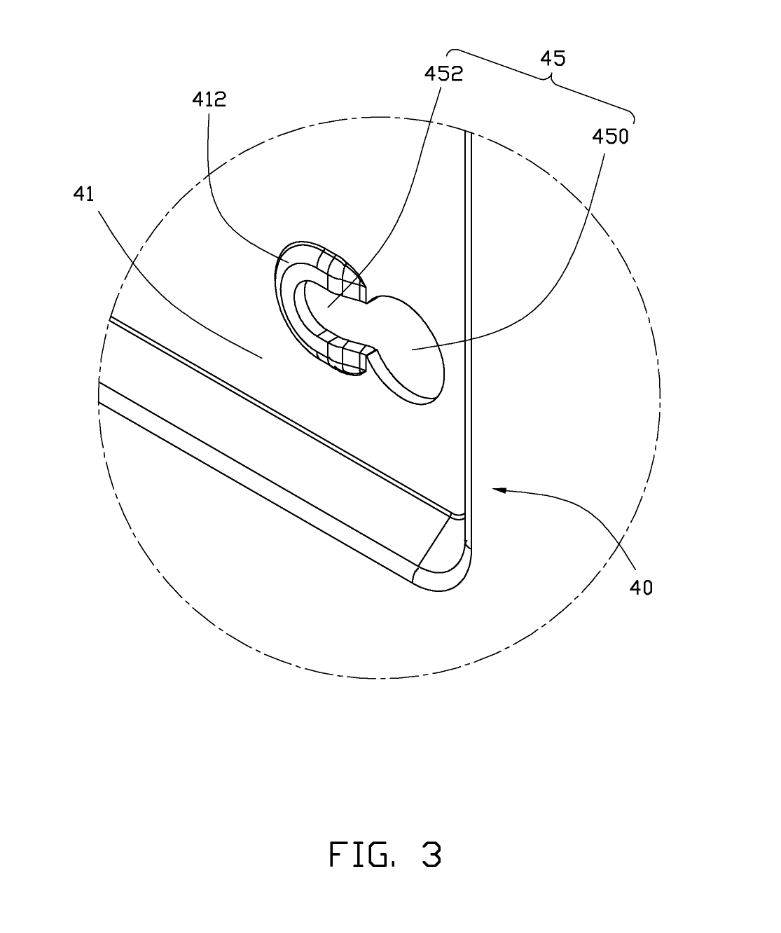

FIG. 1 to FIG. 3 show that the chassis 10 comprises a bottom plate 11 and four flanges 15 extending from four edges of the bottom plate 11. A plurality of installation posts 12 extend from the bottom plate 11. In one embodiment, each flange 15 is substantially perpendicular to the bottom plate 11.

The circuit board 20 defines four installation holes 214. A heating element 23 is secured to the circuit board 20. The four installation holes 214 surround the heating element 23. The plurality of installation posts 12 surrounds the circuit board 20.

The cooling module 30 comprises a cooler 31 and a cooling layer 33 located on the cooler 31. The cooler 31 comprises a body 35 and four mounting members 36. The body 35 comprises a top portion 350, a bottom portion 352, and a side portion 354 connected to the top portion 350 and the bottom portion 352. The top portion 350 is substantially parallel to the bottom portion 352. The cooling layer 33 is located on the top portion 350. The bottom portion 352 defines four locking holes 3520 corresponding to the four installation holes 214.

Each mounting member 36 comprises a mounting post 360, a resilient member 362, and a mounting piece 364. The mounting post 360 comprises a head portion 3600, a connecting portion 3602, and a mounting portion 3604. The connecting portion 3602 is connected between the head portion 3600 and the mounting portion 3604. The head portion 3600 comprises an extension portion 3606 connected to the connecting portion 3602, a sliding portion 3607 extending from the extension portion 3606, and an operating portion 3608 extending from the sliding portion 3607. The mounting portion 3604 corresponds to the installation hole 214 and the locking hole 3520 and comprises a plurality of outer threads. The resilient member 362 surrounds the connecting portion 3602. A first end of the resilient member 362 is secured to the head portion 3600, and a second end of the resilient member 362 is secured to the mounting piece 364. The mounting post 360 is slidable relative to the mounting piece 364 by pressing the resilient member 362. In one embodiment, the resilient member 362 is a spring.

In one embodiment, the cooling layer 33 is made of cooling grease. The cooling layer 33 is spread on the top portion 350. The cooling layer 33 has a first thickness and can extend outwards to become thin to have a second thickness, which is smaller than the first thickness.

The housing 40 comprises a front plate 41 and four side plates 43 extending perpendicularly from four edges of the front plate 41. The front plate 41 defines two sliding slots 45 for receiving two of the four mounting members 36. Each sliding slot 45 comprises a guiding portion 450 and a latching portion 452 communicating with the guiding portion 450. The guiding portion 450 is wider than the latching portion 452. A protrusion 412 extends outwards from edges of the latching portion 452 and surrounds the latching portion 452. A securing piece 432 extends from each side plate 430. The securing piece 432 defines a plurality of securing holes 4321 corresponding to the plurality of installation posts 12.

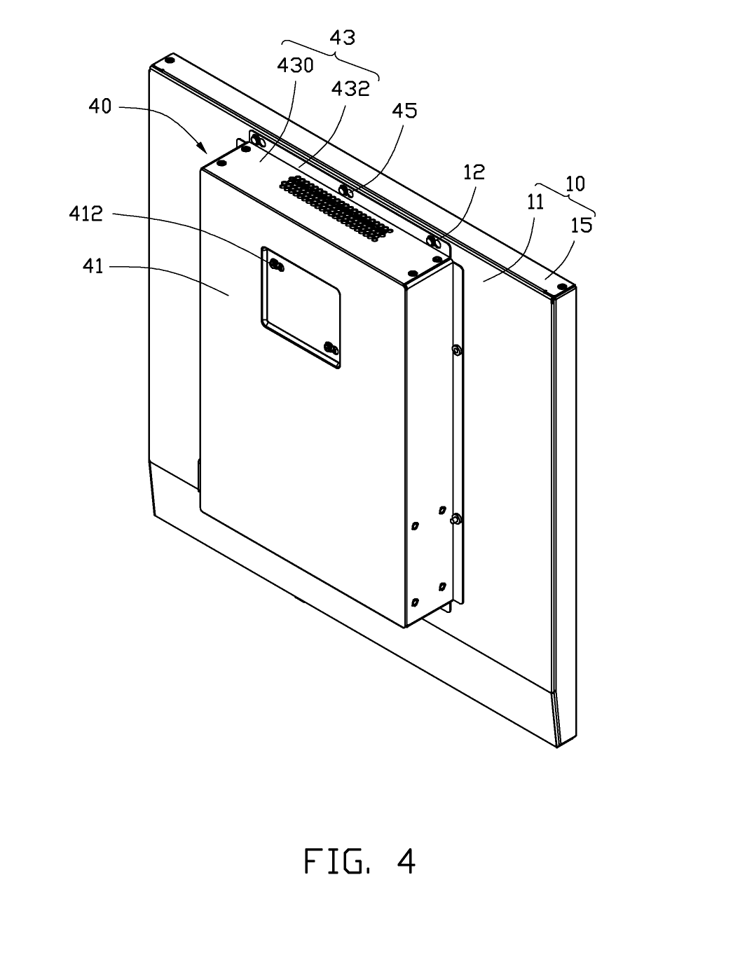

FIG. 4 and FIG. 5 show that in assembly, the mounting members 36 secure the cooling module 30 to the circuit board 20 with each mounting portion 3604 inserting through the corresponded locking hole 3520 and the installation hole 214. A bottom portion 352 abuts the heating element 23. The mounting piece 364 abuts the bottom portion 352. The housing 40 is moved towards the chassis 10 with the operating portion 3608 received in the guiding portion 450. In this position, an inner surface of the front plate 41 abuts the cooling layer 33. The cooling layer 33 has the first thickness, and a first distance between the inner surface of the front plate 41 and cooling layer 33 is smaller than or equal to a thickness of the operating portion 3608. The housing 40 is pressed towards the circuit board 20 to extend the operating portion 3608 out of the guiding portion 450 and receive the sliding portion 3607 in the guiding portion 450. In this position, the cooling layer 33 is pressed by the inner surface of the front plate 41 to extend outwards, having the second thickness smaller than the first thickness. The housing 40 is moved along a direction substantially parallel to the circuit board 20 until the sliding portion 3607 abuts an end of the latching portion 452, the installation posts 12 are engaged in the securing holes 4321 to secure the housing 40 to the chassis 10. When the housing 40 is moved along the direction substantially parallel to the circuit board 20, the inner surface of the front plate 41 expands an area of the cooling layer 33.

In use, the heating element 23 generates heat to the cooler 31. The cooling layer 33 absorbs the heat and transfers the heat to the housing 40, so that the heating element 23 is cooled.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A cooling assembly, comprising:
a chassis;
a circuit board secured to the chassis;
a cooling module comprising a cooling layer and a cooler secured to the circuit board;
a housing receiving the cooler and the circuit board and secured to the chassis; and
wherein the housing comprises a front plate, and the cooler is located between the circuit board and the front plate; the cooling layer is located between the front plate and the cooler; a first surface of the cooling layer is secured to the cooler; and a second surface of the cooling layer, opposite to the first surface, is secured to the front plate.

2. The cooling assembly of claim 1, wherein the cooling module comprises a mounting member, and the mounting member secures the cooler to the circuit board.

3. The cooling assembly of claim 2, wherein the mounting member comprises a mounting post, which comprises a head portion, a connecting portion, and a mounting portion; the head portion and the mounting portion are located on opposite ends of the connecting portion; the mounting portion is secured to the circuit board through the cooler; and the head portion is secured to the front plate.

4. The cooling assembly of claim 3, wherein the mounting member further comprises a mounting piece and a resilient member surrounding the connecting portion, a first end of the resilient member is secured to the mounting piece, and a second end of the resilient member is secured to the head portion.

5. The cooling assembly of claim 4, wherein the cooler comprises a top portion and a bottom portion opposite the top portion, the cooling layer is secured to the top portion, and the bottom portion is configured to abut a heating element secured to the circuit board; and the mounting piece abuts the bottom portion.

6. The cooling assembly of claim 3, wherein the front plate defines a sliding slot, which comprises a guiding portion and a latching portion communicating with the guiding portion, and the guiding portion is wider than the latching portion; the head portion comprises an operating portion and a sliding portion connected to the operating portion; the operating portion extends out of the sliding slot; and the sliding portion is engaged in the latching portion through the guiding portion.

7. The cooling assembly of claim 6, wherein when the operating portion is received in the guiding portion, the cooling layer has a first thickness; when the operating portion extends out of the guiding portion, the cooling layer has a second thickness; and the first thickness is greater than or equal to the second thickness.

8. The cooling assembly of claim 7, wherein when the operating portion is received in the guiding portion, a distance between an inner surface of the front plate and the cooling layer is smaller than or equal to the first thickness of the cooling layer.

9. The cooling assembly of claim 6, wherein an extending direction of the sliding slot is substantially parallel to the circuit board, and the housing is secured to the chassis along the extending direction.

10. The cooling assembly of claim 1, wherein the front plate is substantially parallel to the circuit board.

11. A cooling assembly, comprising:
a chassis;
a circuit board secured to the chassis;
a cooling module comprising a cooling layer, a cooler, and a mounting member securing the cooler to the circuit board;
a housing receiving the cooler and the circuit board and secured to the chassis; and
wherein the mounting member comprises a mounting post and a mounting piece, and the mounting post is slidable relative to the mounting piece along a direction substantially perpendicular to the circuit board; the housing comprises a front plate, and the cooler is located between the circuit board and the front plate; the cooling layer is located between the front plate and the cooler; a first surface of the cooling layer is secured to the cooler; and a second surface of the cooling layer, opposite to the first surface, is secured to the front plate.

12. The cooling assembly of claim 11, wherein the mounting post comprises a head portion, a connecting portion, and a mounting portion, and the head portion and the mounting portion are located on opposite ends of the connecting portion; the mounting portion is secured to the circuit board through the cooler; and the head portion is secured to the front plate.

13. The cooling assembly of claim 12, wherein the mounting member further comprises a resilient member surrounding the connecting portion, a first end of the resilient member is secured to the mounting piece, and a second end of the resilient member is secured to the head portion.

14. The cooling assembly of claim 13, wherein the resilient member is a spring.

15. The cooling assembly of claim 11, wherein the cooler comprises a top portion and a bottom portion opposite the top portion, the cooling layer is secured to the top portion, and the bottom portion is configured to abut a heating element secured to the circuit board; and the mounting piece abuts the bottom portion.

16. The cooling assembly of claim 12, wherein the front plate defines a sliding slot, which comprises a guiding portion and a latching portion communicating with the guiding portion, and the guiding portion is wider than the latching portion; the head portion comprises an operating portion and a sliding portion connected to the operating portion; the operating portion extends out of the sliding slot; and the sliding portion is engaged in the latching portion through the guiding portion.

17. The cooling assembly of claim 16, wherein when the operating portion is received in the guiding portion, the cooling layer has a first thickness; when the operating portion extends out of the guiding portion, the cooling layer has a second thickness; and the first thickness is greater than or equal to the second thickness.

18. The cooling assembly of claim 17, wherein when the operating portion is received in the guiding portion, a distance between an inner surface of the front plate and the cooling layer is smaller than or equal to the first thickness of the cooling layer.

19. The cooling assembly of claim 16, wherein an extending direction of the sliding slot is substantially parallel to the circuit board, and the housing is secured to the chassis along the extending direction.

20. The cooling assembly of claim 11, wherein the front plate is substantially parallel to the circuit board.
